(19) United States
(12) Patent Application Publication
(10) Pub. No.: US 2009/0146278 A1
(43) Pub. Date: Jun. 11, 2009

(54) Chip-stacked package structure with asymmetrical leadframe

(75) Inventor: Geng-Shin Shen, Hsinchu (TW)

Correspondence Address: SINORICA, LLC, 528 FALLSGROVE DRIVE, ROCKVILLE, MD, 20850, US

(73) Assignees: Chipmos Technologies Inc.; Chipmos Technologies (Bermuda) Ltd.

(21) Appl. No.: 11/826,303

(22) Filed: Jul. 13, 2007

(30) Foreign Application Priority Data
Sep. 12, 2006 (TW) 095133660

(51) Int. Cl. H01L 23/538

(52) U.S. Cl. 257/676; 257/E23.175

(57) ABSTRACT

The present invention provides a chip-stacked package structure, comprising: a lead-frame, composed of a plurality of inner leads and a plurality of outer leads, wherein the inner leads comprise a plurality of first inner leads in parallel and a plurality of second inner leads in parallel, and the ends of the first inner leads and the second inner leads are arranged opposite each other at a distance. The first inner leads is provided with a down-set structure, which results in different vertical heights of the position of the end of first inner leads and the position of the end of second inner leads. A chip-stacked package structure is then fixedly connected to the first inner leads, and the metallic bonding pads on the same side edge are electrically connected to the first inner leads and the second inner leads through a plurality of metal wires; and an encapsulant with a top surface and a bottom surface is provided to cover the chip-stacked package structure and the inner leads.

### BACKGROUND OF THE INVENTION

1. Field of the Invention

The present invention relates to a chip-stacked package structure, and more particularly, to a leadframe with inner leads of different height for forming a multi-chip-stacking packaging structure.

2. Description of the Prior Art

In semiconductor post-processing, many efforts have been made for increasing scale of the integrated circuits such as memories while minimizing the occupied area. Accordingly, the development of three-dimensional (3D) packaging technology is in progress and the idea of making up a chip-stacked structure has been disclosed.

The prior art has taught that a chip-stacked structure can be formed by firstly stacking a plurality of chips and then electrically connecting the chips to the substrate in a wire-bonding process. FIG. 11A and FIG. 11B disclose a chip-stacked package structure with lead-frame as its substrate, wherein FIG. 11A is a cross-sectional view and FIG. 11B is a plane view of FIG. 11A. As shown in FIG. 11A, leadframe 5 can be divided into an inner lead portion 5a, an outer lead portion 5b, and a platform portion 5c, wherein there is a height difference between the platform portion 5c, the inner lead portion 5a and the outer lead portion 5b. Firstly, three chips are stacked on the inner lead 5a of the leadframe 5. Then, the pads 7, 8, and 9 are located on the three chips that are connected to the platform portion 5c through metal wires 10, 11, and 12. Then, the molding process is performed to encapsulate three stacked chips, the inner lead 5a of leadframe 5, and the part of platform portion 5c, the outer lead 5b is exposed to connect the leads of other interfaces.

### SUMMARY OF THE INVENTION

In view of the drawbacks and problems of the prior chip-stacked package structure as mentioned above, the present invention provides a three-dimensional chip-stacked structure for packaging multi-chips with similar size.

It is an object of the present invention to provide a chip-stacked package structure with a higher package density and thinner thickness.

It is another object of the present invention to provide a leadframe structure with different height inner leads so as to package with an offset multi-chip-stacked structure.

It is still another object of the present invention to provide a leadframe structure with different height inner leads, so as to adjust the height of the encapsulant according to the number of chips in the offset multi-chip-stacked structure, so that the balance of the injection of the mold-flow can be achieved.

According to abovementioned objects, the present invention provides a chip-stacked package structure, which includes a leadframe having a plurality of inner leads and a plurality of outer leads. The plurality of inner leads comprises a plurality of first inner leads paralleled each other and a plurality of second inner leads paralleled each other. The ends of first inner leads and the second inner leads are arranged in rows facing each other at a distance. The first inner leads are equipped with a down-set structure, which results in different vertical heights of the position of the end of first inner leads and the position of the end of second inner leads. A chip-stacked package structure is then fixedly connected to the first inner leads, and the metallic bonding pads on the same side edge are electrically connected to the first inner leads and the second inner leads through a plurality of metal wires; and an encapsulant with a top surface and a bottom surface is used to encapsulate the chip-stacked package structure and the inner leads.

The present invention also provides a leadframe structure composed of a plurality of inner leads and a plurality of outer leads. The inner leads comprise a plurality of first inner leads that paralleled each other and the second inner leads that paralleled each other. The end of the first inner leads and the end of the second inner leads are arranged in rows facing each other at a distance. The first inner leads are equipped with a down-set structure, which results in different vertical heights of the position of the end of first inner leads and the position of the end of second inner leads.

### BRIEF DESCRIPTION OF THE DRAWINGS

FIG. 11A is a cross-sectional view schematically showing a conventional chip-stacked package structure.

FIG. 11B is a top-elevational view schematically showing the conventional chip-stacked package structure in FIG. 11A.

FIG. 12A is a top-elevational view schematically showing the structure of chip according to the present invention.

FIG. 12B is a cross-sectional view schematically showing the structure of chip according to the present invention.

FIG. 12C is a cross-sectional view schematically showing an offset chip-stacked structure for multi-chip package according to the present invention.

FIGS. 13A to 13C are top-elevational views schematically showing the redistribution layer formed in a process according to the present invention.

FIGS. 14A to 14B are cross-sectional views schematically showing the bonding area on the redistribution layer according to the present invention.

FIG. 15 is a cross-sectional view schematically showing an offset chip-stacked structure with redistribution layer according to the present invention.

FIG. 16 is a cross-sectional view schematically showing a leadframe according to the present invention.

FIG. 17 is a cross-sectional view schematically showing an offset chip-stacked package structure with encapsulant in symmetrical shape according to the present invention.

FIG. 18 is a cross-sectional view schematically showing an offset chip-stacked package structure with encapsulant in symmetrical shape according to another embodiment of the present invention.

FIG. 19 is a cross-sectional view schematically showing an offset chip-stacked package structure with encapsulant in symmetrical shape according to still another embodiment of the present invention.

FIG. 20 is a cross-sectional view schematically showing an offset chip-stacked package structure with encapsulant in asymmetrical shape according to an embodiment of the present invention.

FIG. 21 is a cross-sectional view schematically showing an offset chip-stacked package structure with encapsulant in asymmetrical shape according to another embodiment of the present invention.

FIG. 22 is a cross-sectional view schematically showing an offset chip-stacked package structure with encapsulant in asymmetrical shape according to still another embodiment of the present invention.

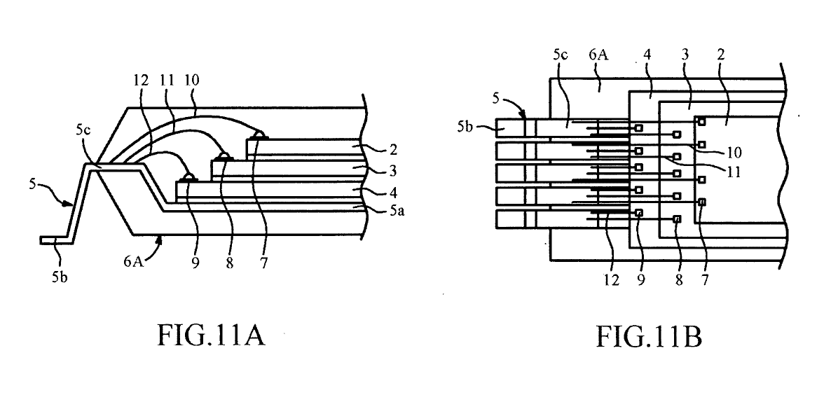

### DESCRIPTION OF THE PREFERRED EMBODIMENT

The present invention will now be described more fully hereinafter with reference to the accompanying drawings, in which preferred embodiments are shown. In the following, the well-known knowledge regarding the chip-stacked structure of the invention such as the formation of chip and the process of thinning the chip would not be described in detail to prevent from arising unnecessary interpretations. However, this invention will be embodied in many different forms and should not be construed as limited to the embodiments set forth herein.

According to the semiconductor packaging process, a Front-End-Process experienced wafer is performed a thinning process to reduce the thickness to a value between 2 mil and 20 mil, and then the polished wafer is applied with a polymer material such as a resin or a B-Staged resin by coating or printing. Next, a post-exposure baking or lighting process is applied to the polymer material so that the polymer material becomes a viscous semi-solidified gel-like material. Subsequently, a removable tape is attached to a gel-like material with viscous semi-solidification, and then the wafer is sawed into chips or dies. At last, each of these chips or dies are stacked on and connected to a substrate to form a chip-stacked structure.

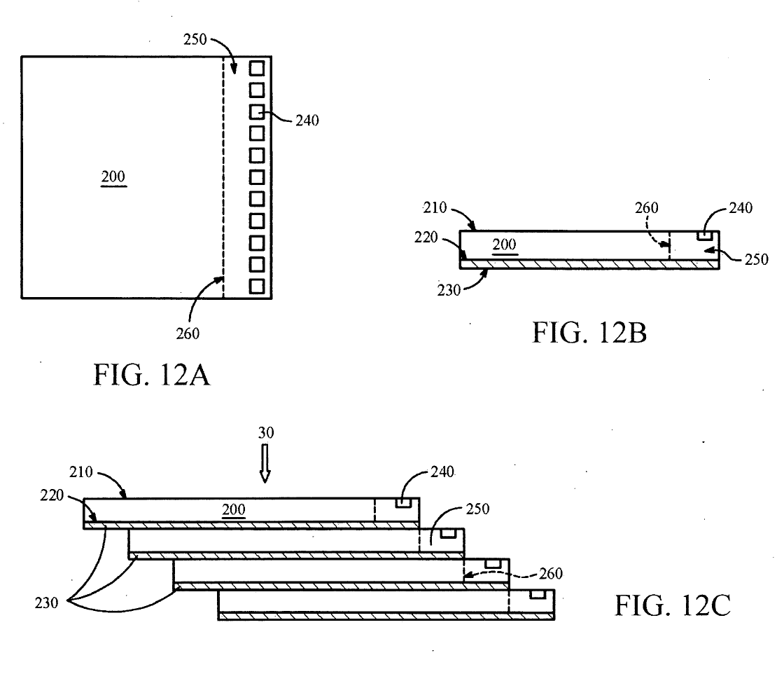

Referring to FIGS. 12A and 12B, show a plane view and a cross-section view for the chip is formed according to abovementioned process. As shown in FIG. 12B, a chip 200 has an active surface 210 and a back surface 220 in opposition to the active surface 210, and the back surface 220 has an adhesive layer 230 thereon. It is to be noted that the adhesive layer 230 is not limited to the semi-solidified gel-like material as abovementioned, the material of the adhesive layer 230, such as a die-attached film, for connecting the chip 200 to a substrate.

Then, referring to FIG. 12C, show a cross-sectional view of a completed offset chip-stacked structure for multi-chip package of the present invention. As shown in FIG. 12C, the active surface 210 of the chip 200 includes a plurality of pads 240 thereon and arranged one side edge along the chips 200. Thus, after an offset connection is performed between the adhesive layer 230 of the back surface 220 and the active surface 210 of another chip 200, an offset multi-chip-stacked structure 30 can be obtained. The offset multi-chip-stacked structure 30 is a ladder-like structure that is formed by aligning the side edge of upper chips with the edge line 260 of the bonding area 250 on the lower chips. Herein, the edge line 260 is a presumed line for reference line, but did not exist on the chip 200. It is to be noted that the adhesive layer 230 is not limited to the above-mentioned semi-solidified gel-like material and can be any adhesive material for connecting the chip 200 and a substrate together.

In another embodiment of offset chip-stacked structure of the present invention, the pads of each chips is provided on the one side of the chips on the wafer by the redistribution layer to form an offset chip-stacked structure. Moreover, the embodiment of the redistribution layer is described as follows.

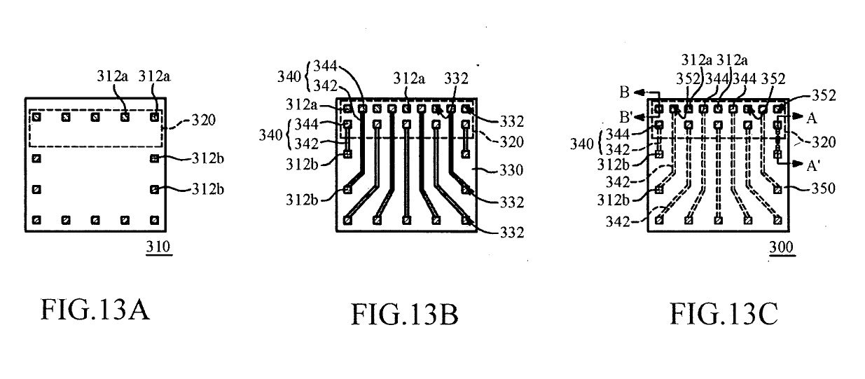

Referring to FIGS. 13A to 13C, show the schematic representation the forming process of the chip with the redistribution layer. As shown in FIG. 13A, the chip 310 is first provided. One side edge adjacent to the chip 310 is designed as a bonding area 320. A plurality of pads 312 are divided into a first pads 312a and a second pads 312b on the active surface of chip 310. The first pads 312a are located inside a bonding area 320, while the second pads 312b are located outside the bonding area 320. As shown in FIG. 13B, a first passivation layer 330 is formed on the chip 310, in which the first passivation layer 330 having a plurality of first openings 332 to expose the first pads 312a and the second pads 312b. Then, a redistribution layer 340 having a plurality of conductive wires 342 and a plurality of third pads 344 is formed on the first passivation layer 330. The third pads 344 are located inside the bonding area 320 and the conductive wires 342 are extended respectively from the second pads 312b to the third pads 344 and are electrically connected to the second pads 312b and the third pads 344. The redistribution layer 340 is made up of conductive materials such as gold, copper, nickel, titanium tungsten, titanium or others. As shown in FIG. 13C, after the chip structure 300 is completed, a second passivation layer 350 with a plurality of second openings 352 is formed on the redistribution layer 340 to cover the area rather than the first pads 312a and the third pads 344, and the first pads 312a and the third pads 344 being exposed.

It is to be noted that the first pads 312a and the second pads 312b can be arranged on the active surface of the chip 310, and also can be arranged in an area array type or other types. Herein, the second pads 312b are electrically connected with the third pads 344 via the conductive wires 342. Moreover, the arrangement of the third pads 344 can be in a manner of being along side edge of the chip 310 and in parallel to the pads 312a as shown in FIG. 13B, or the third pads 344 are located inside the bonding area 320.

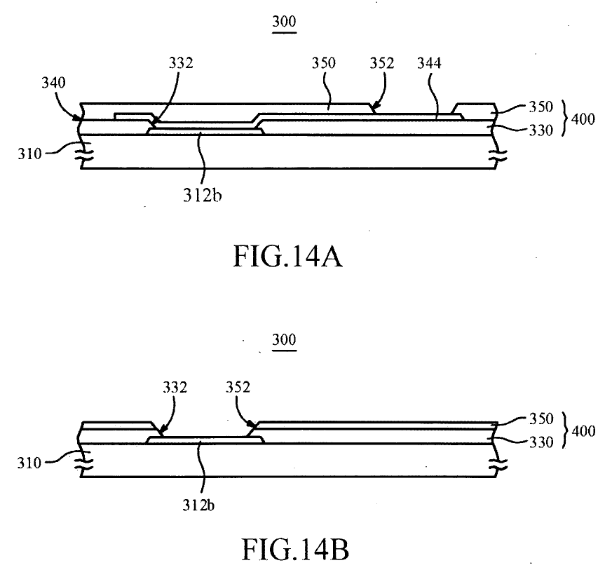

Referring now to FIGS. 14A and 14B, show the cross-sectional views drawn along the section lines A-A′ and B-B′. As shown in FIGS. 14A and 14B, the chip structure 300 is composed of the chip 310 and the redistribution layer 400. The redistribution layer 400 is composed of a first passivation layer 330, a redistribution layer 340, and a second passivation layer 350. The bonding area 320 is adjacent to one side edge of the chip 310. Moreover, the chip 310 has a plurality of first pads 312a and second pads 312b, wherein the first pads 312a are provided with inside the bonding area 320 and the second pads 312b are provided with outside the bonding area 320.

The first passivation layer 330 having a plurality of first opening 332 on the chip 320 to expose these first pads 312a and the second pads 312b. The redistribution layer 340 having a plurality of third pads 344 that is disposed on the first passivation layer 330 and is extended to the bonding area 320 from the second pads 312b. The second passivation layer 350 covers over the redistribution layer 340 and expose the first pads 312a and the third pads 344 through a plurality of second openings 352. Since the first pads 312a and third pads 344 are located in the bonding area 320, and the area rather than the bonding area 320 on the second passivation layer 350 that is capable of carrying another chip and therefore accomplishing an offset multi-chip-stacked structure.

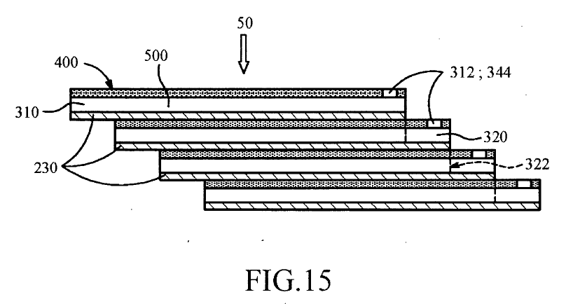

Referring to FIG. 15, which is the cross-sectional view of another offset chip-stacked structure of the present invention. As shown in FIG. 15, an offset chip-stacked structure 50 includes a plurality of stacked chips 500. Each of the chips 500 is formed with a redistribution layer 400 so that each of the chips 500 can be provided with pads inside the bonding area 320 on each chip. In this way, as shown in FIG. 15, the offset chip-stacked structure 50 is a ladder-like structure formed by aligning the side edge of upper chips with a presumed edge line of the bonding area 320 on lower chips and an adhesive layer 230 is used to connect any two chips among the plurality of chips 500. First of all, the adhesive layer 230 between chips 500 is on the back surface of chips 500. The forming method of this adhesive layer 230 is shown in FIG. 12B and the formation of the adhesive layer and the chip are accomplished at the same time. The active surface of chips 500 is provided with redistribution layer 400, and thus all pads (pads 312a or 344) on the chips can be disposed on the bonding area 320 of chips 500. Thus, after the offset connection between the adhesive layer 230 on the back surface of one chip 500 and the redistribution layer 400 of another chip 500 is accomplished, an offset chip-stacked structure 50 is formed.

In the following, two offset chip-stacked structures each connected with leadframes according to the present invention will be disclosed, in which the above-mentioned offset multi-chip-stacked structure 50 will be taken as an example for illustration. However, the following descriptions can also be applied to the above-mentioned offset multi-chip-stacked structure 30.

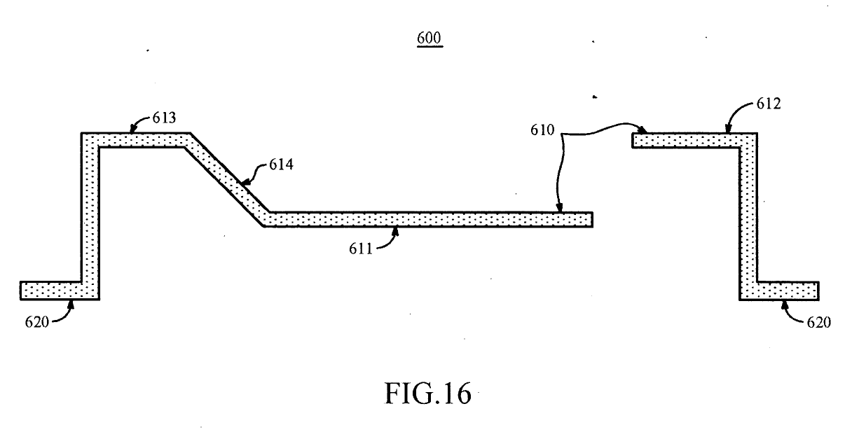

First, referring to FIG. 16, which is a cross-sectional view of the leadframe of the present invention. As shown in FIG. 16, the leadframe 600 includes a plurality of inner leads 610 and a plurality of outer leads 620 arranged in pairs. Wherein the inner leads 610 includes a plurality of first inner leads 611 and second inner leads 612 in parallel. There is a space between the ends of first inner leads 611 and the ends of second inner leads 612 so that the first inner leads 611 and the second inner leads 612 are arranged in pairs. The first inner leads 611 and the second inner leads 612 have different heights. As shown in FIG. 16, first inner leads 611 are provided with a down-set structure formed by a platform portion 613 and a connecting portion 614, wherein the platform portion 613 and the second inner leads 612 have the same height. In addition, the shape of the connecting portion 614 is not limited in the present invention and can be a slope or a near-vertical surface. It should also be noted that the platform portion 613 and the connecting portion 614 can also be a part of first inner leads 611.

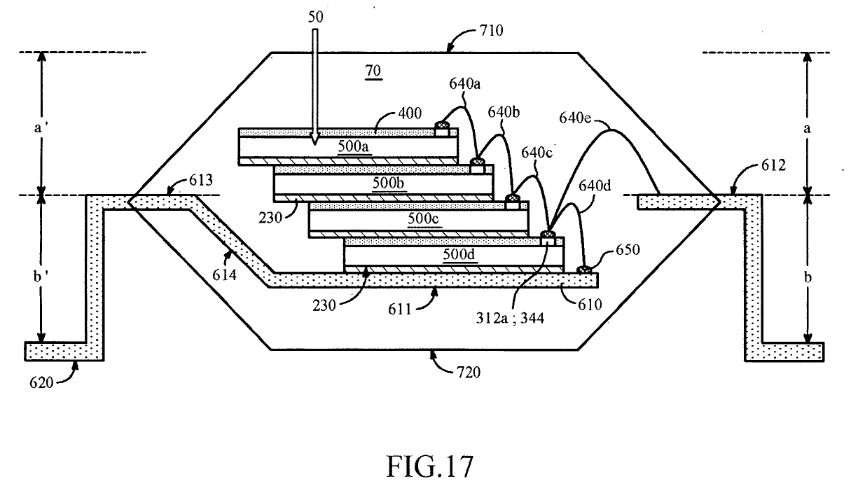

Then, referring to FIG. 17, which is a cross-sectional view of an offset chip-stacked package structure of the present invention. First, as shown in FIG. 17, an adhesive layer 230 is used to attach the first inner leads 611 to the offset chip-stacked structure 50 of leadframe 600. It is obvious that the adhesive layer 230 is attached to the back surface of chips 500, as shown in FIG. 12. Moreover, the adhesive layer 230 can also be disposed on the first inner leads 611 of leadframe 600 and connected to the offset chip-stacked structure 50. Furthermore, a tape, and more particularly, a die attached film, can also be used to attach the first inner leads 611 of leadframe 600 to the offset chip-stacked structure 50 in the present embodiment.

After the connection of the leadframe 60 and the offset chip-stacked structure 50 is accomplished, the connection of metal wires is then processed. Referring to FIG. 17, the metal wire 640a has one end connected to a pad of the chip 500a, such as the first pad 312a or the third pad 344 in FIG. 13 mentioned above, and has the other end connected to a pad of the chip 500b such as the first pad 312a or the third pad 344 in a wire-bonding process. Similarly, the metal wire 640b has one end connected to the first pad 312a or the third pad 344 of the chip 500b, and has the other end connected to the first pad 312a or the third pad 344 of the chip 500c in a wire-bonding process. The metal wire 640c has one end connected to the first pad 312a or the third pad 344 of the chip 500c, and has the other end connected to the first pad 312a or the third pad 344 of the chip 500d in a wire-bonding process. The metal wire 640d has one end connected to the first pad 312a or the third pad 344 of the chip 500a and has the other end connected to the first inner leads 611 of leadframe 600 in a wire-bonding process. The metal wire 640e has one end connected to the first pad 312a or the third pad 344 of the chip 500d and the other end connected to the second inner leads 612 in a wire-bonding process. In this way, the chips 500a, 500b, 500c and 500d are electrically connected to the first inner leads 611 and second inner leads 612 of leadframe 600 when the wire-bonding processes of the metal wires 640a, 640b, 640c, 640d, and 640e are completed. These metal wires 640a, 640b, 640c, 640d, and 640e can be gold made wires in one example. Finally, in the offset chip-stacked package structure that has experienced electrical connection, an encapsulant 70 is used to cover the offset chip-stacked structure 50 and the platform portion 613 and second inner leads 612 of leadframe 600 and expose the outer leads 620 of leadframe 600, and a chip-stacked package structure is formed.

In addition to the above-mentioned process, the connection between leadframe 600 and offset chip-stacked structure 50 through metal wires can also be accomplished by first processing the wire-bonding processes of chips 500a, 500b, 500c, and 500d after the structure of offset chip-stacked structure 50 is completed. The connecting processes are the same as the above-mentioned processes. After the offset chip-stacked structure 50 that has experienced electrical connection and the leadframe 600 are attached to each other, the wire-bonding process is performed again to connect the offset chip-stacked structure 50 and the inner leads 610 of leadframe 600. Thus, the structure in FIG. 17 can be formed.

Moreover, after the leadframe 600 and the offset chip-stacked structure 50 are fixedly connected and before the wire bonding process of metal wire 640 is started, a stud bump 650 is first formed on first pad 312a and third pad 344 in bonding area 320 of chip 500. The connection of above-mentioned metal wires 640a, 640b, 640c, 640d, and 640e are then processed to electrically connect chips 500a, 500b, 500c, and 500d to first inner leads 611 and second inner leads 612 of leadframe 600. This stud bump 650 is provided as a spacer in order to decrease the curve of metal wires 640a, 640b, 640c, 640d, and 640e. It should be noted that the process of forming the stud bump 650 and the process of forming metal wires 640 can be performed simultaneously. In other words, the stud bump 650 and the metal wires 640 can be formed by using the same apparatus. Therefore, the disposition of stud bump 650 in addition does not make the process more difficult or complicate.

As described in the above embodiments, the number of the chips of the chip-stacked structure 50 is not so limited, and any person skilled in the art could manufacture a chip-stacked structure including three chips according to the above-disclosed method. Meanwhile, the offset chip-stacked structure 50 in the embodiment in FIG. 17 can also be replaced by offset chip-stacked structure 30. Since the wire-bonding process of the offset chip-stacked structure 30 performed after the connection to leadframe 600 and the wire-bonding process of the offset chip-stacked structure 50 performed after the connection to leadframe 600 disclosed above are the same, the process would not be given unnecessary details herein.

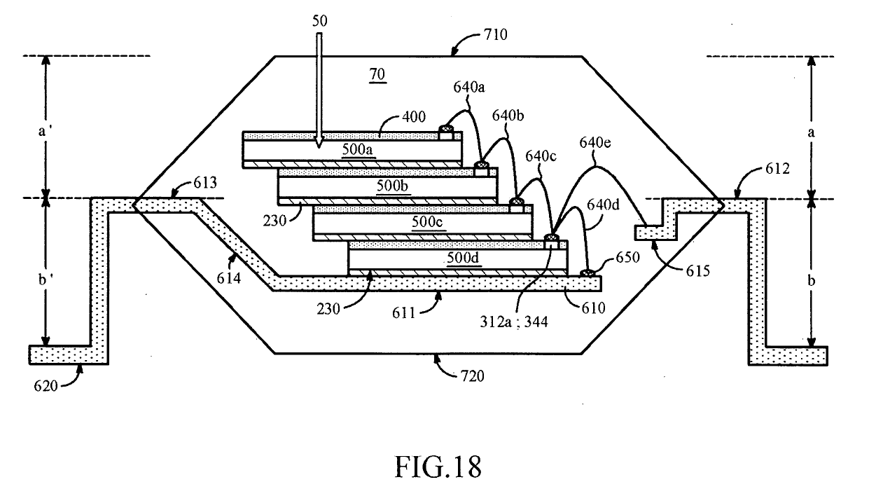

Then, referring to FIG. 18, which is a cross-sectional view of another embodiment of offset chip-stacked package structure of the present invention. As shown in FIG. 18, the leadframe 600 includes a plurality of inner leads 610 and a plurality of outer leads 620 arranged in pairs. Wherein the inner leads 610 includes a plurality of first inner leads 611 and second inner leads 612 in parallel. There is a space between the ends of first inner leads 611 and the ends of second inner leads 612 so that the first inner leads 611 and the second inner leads 612 are arranged in pairs. The first inner leads 611 and the second inner leads 612 have different heights. As shown in FIG. 18, part of first inner leads 611 is a down-set structure formed by a platform portion 613 and a connecting portion 614 which is the same as what is shown in FIG. 17. And the second inner leads 612 is similar to the second inner leads 612 in FIG. 17 except for a concave ladder-like structure 615 formed at the end. It is obvious that the different between the present embodiment and FIG. 17 is the concave ladder-like structure 615 formed at the end of second inner leads 612. The end of this concave ladder-like structure 615 is lower than the second inner leads 612, and thus the metal wire 640e can connect the chip 500d with the end of the concave ladder-like structure 615 when the connection of metal wires 640 is processed, which leads to the decrease in curve of metal wire 640e. Since the connection processes of metal wires in FIG. 17 and in FIG. 18 are the same, thus the process in FIG. 18 would not be given unnecessary details herein.

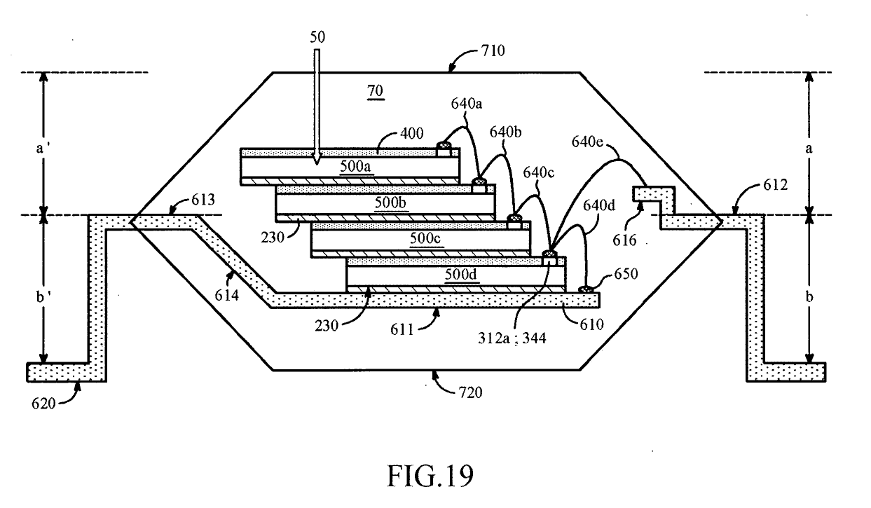

Then, referring FIG. 19, which is a cross-sectional view of still another embodiment of offset chip-stacked package structure of the present invention. The difference between FIG. 19 and FIG. 18 is that the end of second inner leads 612 in FIG. 19 is a protrusive ladder-like structure 616. It is obvious that the end of this protrusive ladder-like structure 616 is higher than the second inner leads 612, so metal wire 640e can connect 500d to the end of the protrusive ladder-like structure 616 when the connection of metal wires 640 is processed. Thus, a chip-stacked package structure can be formed. Since the connection processes of metal wires in FIG. 17, in FIG. 18, and in FIG. 19 are the same, thus the process in FIG. 19 would not be given unnecessary details herein.

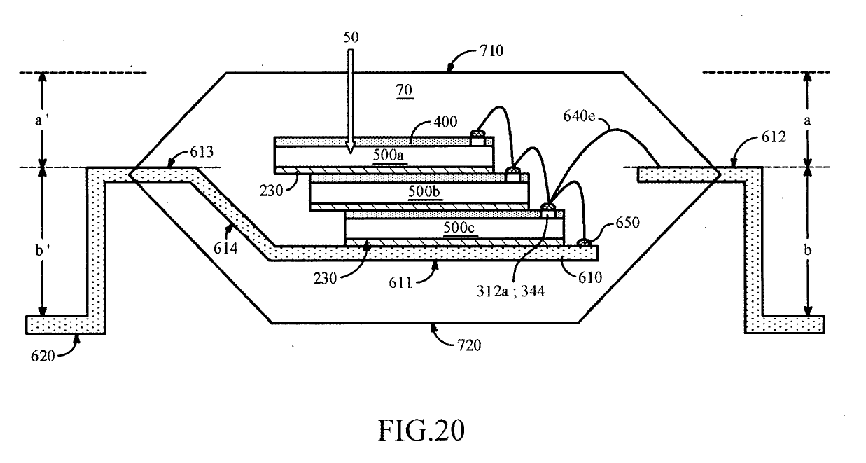

In the following, the encapsulant structure of the present invention is further described. Referring to FIGS. 17 and 20, show the cross-sectional views of an embodiment of encapsulant of the present invention. The encapsulant 70 of the present invention is formed by the molding process. The molds used in the molding process can have different shapes as the number of the chips in the offset chip-stacked structure 30 or offset chip-stacked structure 50 changes. First of all, in FIG. 17, the encapsulant 70 has a top surface 710 and a bottom surface 720. Since the first inner leads 611 of the leadframe 600 of the present invention is provided with a down-set structure formed by a platform portion 613 and a connecting portion 614, and the platform portion 613 and the second inner leads 612 have the same height, thus the first inner leads 611 and the second inner leads 612 have different heights. After the molding process is accomplished, on the side of first inner leads 611, the vertical distance (a′) from the top surface 710 of encapsulant 70 to the platform portion 613 and the vertical distance (b′) from the bottom surface 720 of encapsulant 70 to the platform portion 613 will be the same; on the side of second inner leads 612, the vertical distance (a) from the top surface 710 of encapsulant 70 to the second inner leads 612 and the vertical distance (b) from the second inner leads 612 to the bottom surface 720 of encapsulant 70 will also be the same. It is obvious that the shape of encapsulant 70 in the present embodiment is symmetrical and thus a=b=a′=b′. In this encapsulant structure, when the upper chip in offset chip-stacked structure 30 or offset chip-stacked structure 50 such as chip 500a or 500b is higher than the platform portion 613 of leadframe or second inner leads 612, the depth of down-set structure formed by first inner leads 611 can be adjusted so that the space between the uppermost chip (chip 500a for example) of offset chip-stacked structure 30 or offset chip-stacked structure 500 and the top surface 710 of encapsulant 70 and the space between the down-set structure formed by the first inner leads 611 and the bottom surface 720 of encapsulant 70 can become close to each other. Thus, when the molding process is performed, the mold-flow flowing above chip 500a and the mold-flow flowing below the down-set structure formed by the first inner leads 611 can be balanced to form the symmetrical package structure disclosed by the present embodiment. In addition, the present embodiment can also be applied when the second inner leads 612 of leadframe 600 is provided with a concave ladder-like structure 615 or a protrusive ladder-like structure 616, as shown in FIGS. 18 and 19.

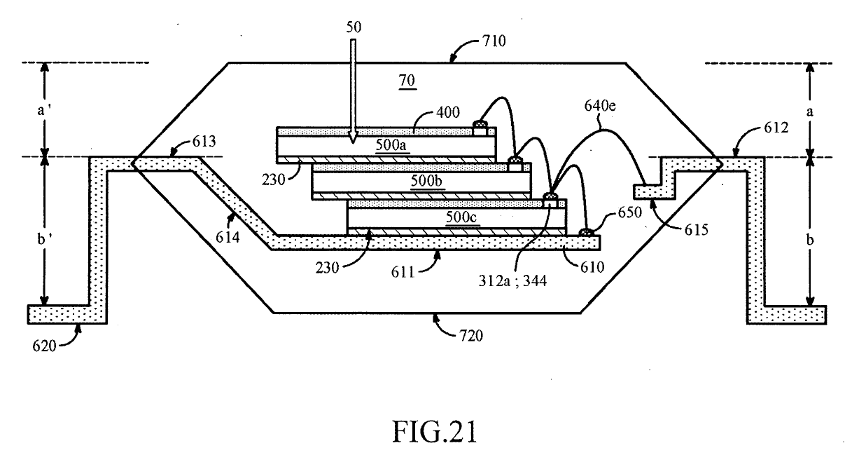

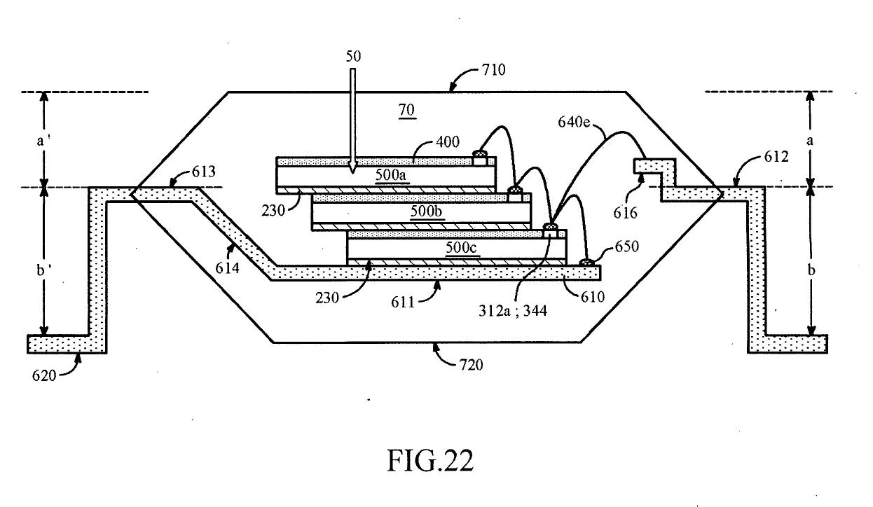

Moreover, when the uppermost chip (chip 500a for example) of offset chip-stacked structure is slightly lower or slightly higher than the platform portion 613 and the second inner leads 612, the space between the chip 500a fixedly connected to the down-set structure and the top surface 710 of encapsulant 70 is larger than the space between the down-set structure of first inner leads 611 and the bottom surface 720 of encapsulant 70 since the first inner leads 611 of leadframe 600 is a down-set structure. In this way, when the molding process is performed the mold-flow flowing above chip 500a and the mold-flow flowing below the down-set structure of first inner leads 611 become unbalanced and thus affects the yield of the molding process. Therefore, the structure of molds used in the molding process can be adjusted in the present embodiment. For example, the upper mold can be lowered so that the space between the uppermost chip (chip 500a for example) of offset chip-stacked structure 30 or offset chip-stacked structure 50 and the top surface 710 of encapsulant 70 and the space between the down-set structure formed by first inner leads 611 and the bottom surface 720 of encapsulant 70 can be close to each other. Thus, the mold-flow flowing above chip 500a and the mold-flow flowing below the down-set structure of first inner leads 611 can become balanced in the molding process. After the molding process is accomplished, the vertical distance (a′) from the top surface 710 of encapsulant 70 to the platform portion 613 and the vertical distance (a) from the top surface 710 of encapsulant 70 to the second inner leads 612 are different from the vertical distance (b′) from the platform portion 613 to the bottom surface 720 of encapsulant 70 and the vertical distance (b) from the second inner leads 612 to the bottom surface 720 of encapsulant 70, as shown in FIG. 20. It is obvious that the upper half and the lower half of encapsulant 70 in the present embodiment are not symmetrical. In other words, a=a′, b=b′, and the vertical distance a is shorter than the vertical distance b. It should be noted that the object of using molds to shorten the vertical distance (a′) from the top surface 710 of encapsulant 70 to the platform portion 613 and the vertical distance (a) from the top surface 710 of encapsulant 70 to the second inner leads 612 is not only to reduce the usage of encapsulating material, but also, more importantly, to keep the mold-flows in the molding process in balance. In addition, the height of the down-set structure of first inner leads 611 can also be changed for adjusting the distance of a:b (or a′:b′). In the embodiment disclosed in the present invention, when a:b (or a′:b′) is 1:3, the mold-flow flowing above chip 500a and the mold-flow flowing below the down-set structure of first inner leads 611 are in perfect balance. In addition, the present embodiment can also be applied when the second inner leads 612 of leadframe 600 is provided with a concave ladder-like structure 615 or a protrusive ladder-like structure 616, as shown in FIGS. 21 and 22.

To summarize, in the front end process not only the chip in the chip-stacked structure provided by the present invention can be provided with a plurality of pads on one side of the chip, but another method is also disclosed. First pad and third pad can be gathered on one side of the chip-stacked structure through proper design of bonding area and the redistribution layer so that the chip-stacked structure can carry other chip structures through area other than the bonding area. Thus, compared to prior chip-stacked package structure, the chip-stacked package structure in which the above-mentioned chip-stacking method is used has larger scale of the integrated circuits and reduced thickness in a package.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A chip-stacked package structure, comprising:
a leadframe comprising a plurality of inner leads and a plurality of outer leads, said inner leads comprising a plurality of first inner leads in parallel and a plurality of second inner leads in parallel, the end of said first inner leads and the end of second inner leads being arranged in rows facing each other at a distance;
a multi-chip-stacked structure fixedly connected to said first inner leads, metallic bonding pads on the same side edge being electrically connected to said first inner leads and said second inner leads through a plurality of metallic wires in said multi-chip-stacked structure; and
an encapsulant with a top surface and a bottom surface covering said multi-chip-stacked structure and said plurality of inner leads;
the improvement of which being:
said first inner leads having a down-set structure which resulting in different vertical heights of the position of end of said first inner leads and the position of end of said second inner leads.

2. The chip-stacked package structure as set forth in claim 1, wherein said end of said second inner leads having a concave ladder-like structure.

3. The chip-stacked package structure as set forth in claim 1, said end of said second inner leads having a protrusive ladder-like structure.

4. The chip-stacked package structure as set forth in claim 1, wherein said down-set structure is formed by a platform portion and a connecting portion between said first inner leads and said plurality of outer leads.

5. The chip-stacked package structure as set forth in claim 1, wherein said second inner leads and said platform portion have the same height.

6. The chip-stacked package structure as set forth in claim 1, wherein the vertical distance from the top surface of said encapsulant to said second inner leads and to said platform portion and the vertical distance from said second inner leads and said platform portion to the bottom surface of said encapsulant are the same.

7. The chip-stacked package structure as set forth in claim 1, wherein the vertical distance from the top surface of said encapsulant to said second inner leads and to said platform portion and the vertical distance from said second inner leads and said platform portion to the bottom surface of said encapsulant are different.

8. The chip-stacked package structure as set forth in claim 1, wherein the vertical distance from the top surface of said encapsulant to said second inner leads and to said platform portion is shorter than the vertical distance from said second inner leads and said platform portion to the bottom surface of said encapsulant.

9. The chip-stacked package structure as set forth in claim 1, wherein the vertical distance from the top surface of said encapsulant to said second inner leads and to said platform portion and the vertical distance from said second inner leads and said platform portion to the bottom surface of said encapsulant are in the ratio of 1 to 3.

10. The chip-stacked package structure as set forth in claim 4, wherein said connecting portion can be a slope or a near-vertical surface.

11. The chip-stacked package structure as set forth in claim 1, wherein the chips of the offset multi-chip-stacked structure each comprising:
a body having a bonding area located close to one side edge of the body, a plurality of first pads being formed inside the bonding area and a plurality of second pads being formed outside the bonding area;
a first passivation layer provided on said body with a plurality of first openings formed on the fist passivation layer to expose said plurality of first pads and said plurality of second pads;
a redistribution layer formed with a plurality of third pads inside the bonding area being provided on said first passivation layer for establishing connection between said plurality of second pads and said bonding area;
a second passivation layer provided to cover said redistribution layer with a plurality of second openings formed on said second passivation layer to expose said plurality of first pads and said plurality of third pads.

12. The chip-stacked package structure as set forth in claim 11, wherein said first pads and said third pads are further provided with the structure of bump stud.

13. The chip-stacked package structure as set forth in claim 1, wherein the top surface of said first inner leads is provided with an adhesive layer for fixedly connecting said multi-chip-stacked structure.

14. The chip-stacked package structure as set forth in claim 1, wherein a layer of polymer material is attached to the back surface of each chip in said multi-chip-stacked structure.

15. A leadframe structure comprising a plurality of inner leads and a plurality of outer leads, said inner leads comprising a plurality of first inner leads in parallel and a plurality of second inner leads in parallel, the end of said first inner leads and the end of second inner leads being arranged in rows facing each other at a distance, the improvement of which being:
said first inner leads having a down-set structure which resulting in different vertical heights of the position of end of said first inner leads and the position of end of said second inner leads.

16. The leadframe structure as set forth in claim 15, wherein the end of said second inner leads has a protrusive ladder-like structure.

17. The leadframe structure as set forth in claim 15, wherein the end of said second inner leads has a concave ladder-like structure.

18. The leadframe structure as set forth in claim 15, wherein said down-set structure is formed by a platform portion and a connecting portion between said first inner leads and said plurality of outer leads.

19. The leadframe structure as set forth in claim 18, wherein said second inner leads and said platform portion are vertically at the same height.

20. The leadframe structure as set forth in claim 18, wherein said connecting portion can be a slope or a near-vertical surface.
